(19) United States
(12) Patent Application Publication
(10) Pub. No.: US 2026/0006966 A1
(43) Pub. Date: Jan. 1, 2026

(54) DISPLAY DEVICE

(71) Applicant: Samsung Display Co., LTD., Yongin-si (KR)

(72) Inventors: Byoung Yong KIM, Yongin-si (KR); Byung Choon YANG, Yongin-si (KR); Dong Jun LEE, Yongin-si (KR)

(73) Assignee: Samsung Display Co., LTD., Yongin-si (KR)

(21) Appl. No.: 19/169,373

(22) Filed: Apr. 3, 2025

(30) Foreign Application Priority Data
Jun. 28, 2024 (KR) 10-2024-0085675

(51) Int. Cl. H10H 29/80

(52) U.S. Cl. CPC H10H 29/8321

(57) ABSTRACT

A display device includes a cathode extending in a first direction, an anode spaced apart from the cathode by a first gap in a second direction intersecting the first direction, and a light-emitting element electrically connected to the cathode and the anode. A second gap in the second direction between the cathode and the anode facing each other is greater than the first gap.

### CROSS-REFERENCE TO RELATED APPLICATION(S)

This application claims priority to and benefits of Korean Patent Application No. 10-2024-0085675 under 35 U.S.C. § 119, filed on Jun. 28, 2024, in the Korean Intellectual Property Office (KIPO), the entire contents of which are incorporated herein by reference.

### BACKGROUND

### 1. Technical Field

Embodiments relate to a display device.

### 2. Description of the Related Art

With the development of information technology, importance of a display device which is a connecting medium between a user and information is emphasized.

The display device may include light-emitting elements, and the light-emitting elements may be bonded to corresponding anodes and cathodes. A high-resolution display device has a high pixel density, and a short circuit failure may occur due to misalignment of the light-emitting element in bonding the light-emitting element.

### SUMMARY

Embodiments provide a display device for preventing misalignment and short circuit failure of a light-emitting element.

However, embodiments are not limited to those set forth herein. The above and other embodiments will become more apparent to one of ordinary skill in the art to which the disclosure pertains by referencing the detailed description of the disclosure given below.

According to an embodiment, a display device may include a cathode extending in a first direction, an anode spaced apart from the cathode by a first gap in a second direction intersecting the first direction, and a light-emitting element electrically connected to the cathode and the anode, and a second gap in the second direction between the cathode and the anode facing each other may be greater than the first gap.

The second gap may change along the first direction.

The second gap may increase along the first direction.

An edge of the anode facing the cathode may be diagonal, and an edge of the cathode facing the anode may be straight.

An edge of the anode facing the cathode may be a curved shape, and an edge of the cathode facing the anode may be straight.

The curved shape may be convex upward.

The curved shape may be concave downward.

The second gap may decrease along the first direction.

An edge of the cathode facing the anode may be diagonal, and an edge of the anode facing the cathode may be straight.

The second gap may be constant along the first direction.

An edge of the anode facing the cathode and an edge of the cathode facing the anode each may be diagonal.

The second gap may increase and decrease along the first direction.

An edge of the anode facing the cathode may be V-shaped, and an edge of the cathode facing the anode may be straight.

An edge of the cathode facing the anode may be an inverted V shape, and an edge of the anode facing the cathode may be straight.

An edge of the anode facing the cathode may be V-shaped, and an edge of the cathode facing the anode may be an inverted V shape.

The second gap may repeatedly increase and decrease along the first direction.

An edge of the anode facing the cathode may be saw-toothed, and an edge of the cathode facing the anode may be straight.

An edge of the cathode facing the anode may be saw-toothed, and an edge of the anode facing the cathode may be straight.

An edge of the anode facing the cathode and an edge of the cathode facing the anode each may be saw-toothed.

According to an embodiment, an electronic device may include a display device including a display element layer disposed on a substrate. The display element layer may include a cathode extending in a first direction, an anode spaced apart from the cathode by a first gap in a second direction intersecting the first direction, and a light-emitting element electrically connected to the cathode and the anode. A second gap in the second direction between the cathode and the anode facing each other may be greater than the first gap. The electronic device may be at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.

### BRIEF DESCRIPTION OF THE DRAWINGS

The above and other features of the disclosure will become more apparent by describing in further detail embodiments thereof with reference to the accompanying drawings, in which:

FIG. 1 is a schematic diagram of a display device according to an embodiment.

FIG. 2 is a schematic diagram of a sub-pixel according to an embodiment.

FIG. 3 is a plan view of a display panel according to an embodiment.

FIG. 4 is a schematic cross-sectional view of a display panel according to an embodiment.

FIG. 5 is a schematic cross-sectional view of a display panel according to an embodiment.

FIG. 6 is a plan view of a pixel according to an embodiment.

FIG. 7 is a schematic cross-sectional view taken along line I-I′ of FIG. 6.

FIG. 8 is a plan view illustrating misalignment of a light-emitting element.

FIG. 9 is a schematic cross-sectional view taken along line II-II′ of FIG. 8.

FIG. 10 is a schematic cross-sectional view illustrating a contact failure due to misalignment of a light-emitting element.

FIG. 11 to FIG. 21 are plan views of a pixel according to embodiments.

FIG. 22 is a schematic diagram of a display system according to an embodiment.

FIG. 23 to FIG. 26 are schematic diagrams of application examples of the display system of FIG. 22.

### DETAILED DESCRIPTION OF THE EMBODIMENTS

Hereinafter, embodiments will now be described in detail with reference to the accompanying drawings. It should be noted that the following explanation describes only parts necessary to understand the operation of the disclosure, and other parts of the description will be omitted not to obscure the gist of the disclosure. In addition, the disclosure is not limited to the embodiments described herein, but may be embodied in other forms. However, the embodiment described herein is provided to explain in such detail as to facilitate implementation of the technical idea of the disclosure to a person skilled in the art to which the disclosure pertains.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Terminology used herein is intended to describe specific embodiments and is not intended to limit the disclosure. The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Herein, terms such as first and second may be used to describe various components, but these components are not limited to these terms. These terms are used to distinguish one component from another component. Accordingly, a first component may be referred to as a second component without departing from the disclosure.

Spatially relative terms such as “below” and “above” may be used for illustrative purposes, thereby describing the relationship of one element or feature to another element(s) or feature(s) as shown in the drawings. The spatially relative term is intended to include different orientations in use, operation, and/or manufacture, in addition to the orientation depicted in the drawing. For example, if a device shown in the drawing is turned over, elements depicted as being positioned “below” other elements or features are positioned “above” the other elements or features. Hence, the term “below” may include both above and below directions in an embodiment. Besides, the device may be oriented in other direction (e.g., rotated 90 degrees or in a different direction), and thus the spatially relative terms used herein are interpreted accordingly.

Various embodiments are described with reference to drawings illustrating embodiments. Accordingly, it is to be expected, for example, that shapes may change depending on tolerances and/or manufacturing techniques. Thus, the embodiments disclosed herein may not be construed as being limited to the specific shapes depicted, but should be construed as including variations of the shapes resulting from, for example, manufacturing. As such, the shapes shown in the drawings may not show actual shapes of areas of the device, and the disclosure is not limited thereto.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments are described in detail with reference to the accompanying drawings.

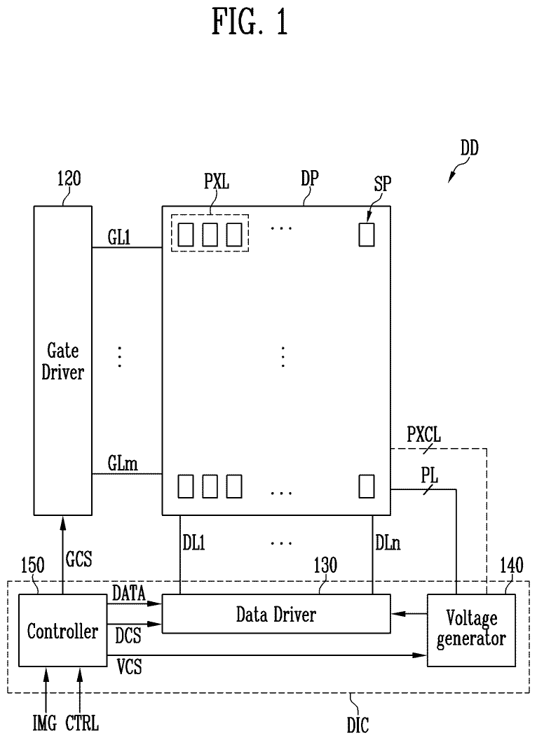

FIG. 1 is a schematic diagram of a display device according to an embodiment.

Referring to FIG. 1, a display device (DD) may include a display panel (DP), a gate driver 120, a data driver 130, a voltage generator 140, and a controller 150.

The display panel (DP) may include sub-pixels (SP). The sub-pixels (SP) may be connected to the gate driver 120 via first through m-th gate lines (GL1˜GLm). The sub-pixels (SP) may be connected to the data driver 130 via first through n-th first data lines (DL1˜DLn).

The sub-pixels (SP) may generate light of two or more colors. For example, each of the sub-pixels (SP) may produce light of red, green, blue, cyan, magenta, or yellow.

Two or more of the sub-pixels (SP) may configure a single pixel (PXL). For example, the pixel (PXL) may include three sub-pixels as shown in FIG. 1. As such, the pixel (PXL) may emit light of various colors and various luminances depending on a combination of the light emitted from the sub-pixels included in the pixel (PXL).

The gate driver 120 may be connected to sub-pixels (SP) arranged in a row direction via the first through m-th gate lines (GL1˜GLm). The gate driver 120 may output gate signals to the first through m-th gate lines (GL1˜GLm) in response to a gate control signal (GCS). The gate control signal (GCS) may include a start signal indicating a start of each frame, a horizontal synchronization signal, and so on.

The gate driver 120 may be disposed on a side of the display panel (DP). However, embodiments are not limited thereto. For example, the gate driver 120 may be divided into two or more drivers physically and/or logically separated, and such drivers may be disposed on a side of the display panel (DP) and another side of the display panel (DP) which is opposite to the side. As such, the gate driver 120 may be disposed adjacent to the display panel (DP) in various forms according to embodiments.

The data driver 130 may be connected to the sub-pixels (SP) arranged in a column direction via the first through n-th data lines (DL1˜DLn). The data driver 130 may receive image data (DATA) and a data control signal (DCS) from the controller 150. The data driver 130 may operate in response to the data control signal (DCS). The data control signal (DCS) may include a source start signal, a source shift clock, a source output enable signal, and so on.

The data driver 130 may receive voltages from the voltage generator 140. Using the received voltages, the data driver 130 may apply data signals having grayscale voltages corresponding to the image data (DATA) to the first through n-th data lines (DL1˜DLn). If a gate signal is applied to each of the first through m-th gate lines (GL1˜GLm), the data signals corresponding to the image data (DATA) may be applied to the first through n-th data lines (DL1˜DLn). Hence, the sub-pixels (SP) may generate light corresponding to the data signals, and the display panel (DP) may display an image.

The gate driver 120 and the data driver 130 may include complementary metal-oxide semiconductor (CMOS) circuit elements.

The voltage generator 140 may operate in response to a voltage control signal (VCS) from the controller 150. The voltage generator 140 may be configured to generate multiple voltages, and to provide the generated voltages to components of the display device (DD) such as the gate driver 120, the data driver 130, and the controller 150. The voltage generator 140 may generate the voltages, by receiving an input voltage from outside of the display device (DD) and regulating the received voltage.

The voltage generator 140 may generate a first power voltage and a second power voltage. The generated first and second power voltages may be provided to the sub-pixels (SP) through power lines (PL). However, embodiments are not necessarily limited thereto, and at least one of the first and second power voltages may be provided from the outside of the display device (DD).

Besides, the voltage generator 140 may provide various voltages and/or signals. For example, the voltage generator 140 may provide one or more initialization voltages to the sub-pixels (SP). For example, in a sensing operation for sensing electrical properties of transistors and/or light-emitting elements of the sub-pixels (SP), a reference voltage may be applied to the first through n-th data lines (DL1˜DLn), and the voltage generator 140 may generate and transmit the reference voltage to the data driver 130. For example, in a display operation for displaying an image on the display panel (DP), common pixel control signals may be applied to the sub-pixels (SP), and the voltage generator 140 may generate the pixel control signals. The voltage generator 140 may provide the pixel control signals to the sub-pixels (SP) via pixel control lines (PXCL). FIG. 1 shows that pixel control lines (PXCL) are connected between the voltage generator 140 and the display panel (DP), but embodiments are not limited thereto. For example, the pixel control lines (PXCL) may be connected between the gate driver 120 and the display panel (DP), and the pixel control signals may be transmitted from the voltage generator 140 to the pixel control lines (PXCL) via the gate driver 120.

The controller 150 may control all operations of the display device (DD). The controller 150 may receive input image data (IMG) and a corresponding control signal (CTRL) from the outside. In response to the control signal (CTRL), the controller 150 may provide a gate control signal (GCS), a data control signal (DCS), and a voltage control signal (VCS).

The controller 150 may output the image data (DATA) by converting the input image data (IMG) for the display device (DD) or the display panel (DP). The controller 150 may output the image data (DATA) by aligning the input image data (IMG) in accordance with the sub-pixels (SP) on a row basis.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit (DIC), and the data driver 130, the voltage generator 140, and the controller 150 may be functionally separate components in a single driver integrated circuit (DIC). However, embodiments are not necessarily limited thereto, and in another embodiment, at least one of the data driver 130, the voltage generator 140, and the controller 150 may be provided as a separate component from the driver integrated circuit (DIC).

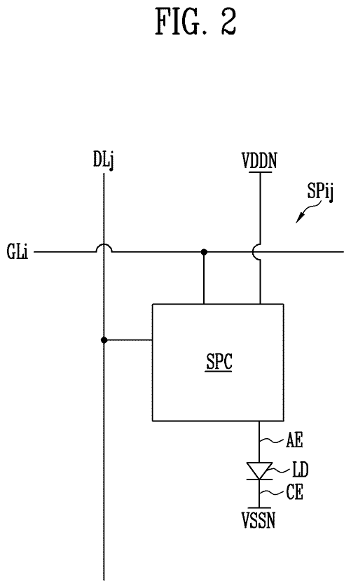

FIG. 2 is a schematic diagram of a sub-pixel according to an embodiment. In FIG. 2, among the sub-pixels (SP) of FIG. 1, a sub-pixel (SPij) arranged in an i-th row (i is an integer greater than or equal to 1 and less than or equal to m) and in a j-th column j (j is an integer greater than or equal to 1 and less than or equal to n) is schematically illustrated.

Referring to FIG. 2, the sub-pixel (SPij) may include a sub-pixel circuit (SPC) and a light-emitting element (LD).

The light-emitting element (LD) may be connected between a first power voltage node (VDDN) and a second power voltage node (VSSN). The first power voltage node (VDDN) may be connected to one of the power lines (PL) of FIG. 1, to receive the first power voltage. The second power voltage node (VSSN) may be connected to another one of the power lines (PL) of FIG. 1, to receive the second power voltage. The first power voltage may have a higher voltage level than the second power voltage.

The light-emitting element (LD) may be connected between an anode (AE) and a cathode (CE). The anode (AE) may be connected to the first power voltage node (VDDN) through the sub-pixel circuit (SPC). For example, the anode (AE) may be connected to the first power voltage node (VDDN) through one or more transistors included in the sub-pixel circuit (SPC). The cathode (CE) may be connected to the second power voltage node (VSSN). The light-emitting element (LD) may be configured to emit light according to a current flowing from the anode (AE) to the cathode (CE).

The sub-pixel circuit (SPC) may be connected to an i-th gate line (GLi) of the first through m-th first gate lines (GL1˜GLm) of FIG. 1, and a j-th data line (DLj) of the first through n-th data lines (DL1˜DLn) of FIG. 1. In response to the gate signal received through the i-th gate line (GLi), the sub-pixel circuit (SPC) may control the light-emitting element (LD) to emit the light according to the data signal received through the j-th data line (DLj). The sub-pixel circuit (SPC) may be further connected to the pixel control lines (PXCL) of FIG. 1, and the sub-pixel circuit (SPC) may control the light-emitting element (LD) in response further to the pixel control signals received through the pixel control lines (PXCL).

For such operations, the sub-pixel circuit (SPC) may include circuit elements, for example, transistors and one or more capacitors.

The transistors of the sub-pixel circuit (SPC) may include P-type transistors and/or N-type transistors. The transistors of the sub-pixel circuit (SPC) may include a metal oxide silicon field effect transistor (MOSFET). The transistors of the sub-pixel circuit (SPC) may include an amorphous silicon semiconductor, a monocrystalline silicon, a polycrystalline silicon semiconductor, an oxide semiconductor, or the like.

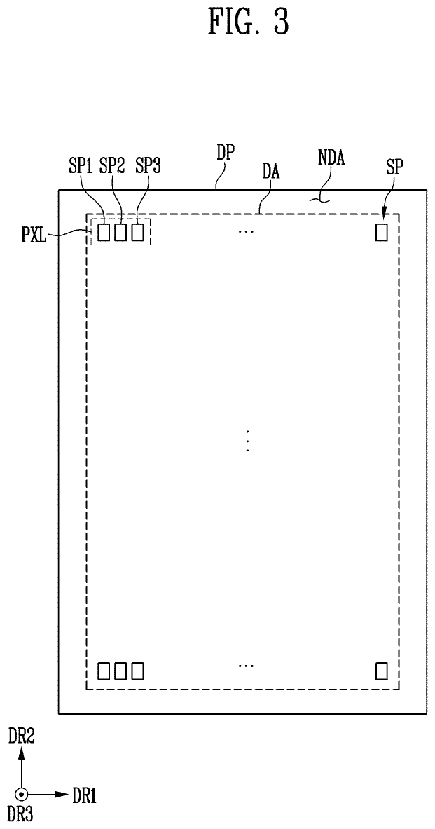

FIG. 3 is a plan view of a display panel according to an embodiment.

Referring to FIG. 3, the display panel (DP) may include a display area (DA) and a non-display area (NDA). The display panel (DP) may display an image through the display area (DA). The non-display area (NDA) may be disposed adjacent to the display area (DA).

The display panel (DP) may include sub-pixels (SP) in the display area (DA). The sub-pixels (SP) may be arranged in a first direction (DR1) and a second direction (DR2) which intersects the first direction (DR1). For example, the sub-pixels (SP) may be arranged in a matrix form in the first direction (DR1) and the second direction (DR2). For example, the sub-pixels (SP) may be arranged in zigzag along the first direction (DR1) and the second direction (DR2). The arrangement of the sub-pixels (SP) may vary according to embodiments. The first direction (DR1) may be a row direction, and the second direction (DR2) may be a column direction.

Two or more of the sub-pixels (SP) may configure one pixel (PXL). FIG. 3 shows that the pixel (PXL) includes three sub-pixels (SP1˜SP3), but embodiments are not limited thereto. For example, the pixel (PXL) may include two sub-pixels. Hereinafter, for the convenience of explanation, an embodiment that a pixel (PXL) includes first through third sub-pixels (SP1˜SP3) will be described.

The first through third sub-pixels (SP1˜SP3) each may generate light of one of various colors such as red, green, blue, cyan, magenta, and yellow. Hereafter, for the sake of clear and concise explanation, an embodiment that the first sub-pixel (SP1) is configured to produce light of red color, the second sub-pixel (SP2) is configured to produce light of green color, and the third sub-pixel (SP3) is configured to produce light of blue color will be described.

The first through third sub-pixels (SP1˜SP3) each may include at least one light-emitting element configured to generate light. The light-emitting elements of the first through third sub-pixels (SP1˜SP3) may generate light of a same color. For example, the light-emitting elements of the first through third sub-pixels (SP1˜SP3) may generate blue-colored light. However, embodiments are not necessarily limited thereto, and the light-emitting elements of the first through third sub-pixels (SP1˜SP3) may produce light of different colors. For example, the light-emitting elements of the first through third sub-pixels (SP1˜SP3) may generate red, green, and blue light respectively.

The display panel (DP) may be a self-luminescent display panel such as an LED display panel which uses a microscale or nanoscale light-emitting diode as the light-emitting element, or an organic light-emitting display panel (OLED panel) which uses an organic light-emitting diode as the light-emitting element.

In the non-display area (NDA), a component for controlling the sub-pixels (SP) may be disposed. Wiring connected to the sub-pixels (SP), for example, the first through m-th gate lines (GL1˜GLm), the first through n-th data lines (DL1˜DLn), the power lines (PL), and the pixel control lines (PXCL) may be disposed in the non-display area (NDA).

At least one of the gate driver 120, the data drivers 130, the voltage generator 140, and the controller 150 of FIG. 1 may be disposed in the non-display area (NDA) of the display panel (DP). In an embodiment, the gate driver 120 may be disposed in the non-display area (NDA), the data driver 130, the voltage generator 140, and the controller 150 may be implemented as a driver integrated circuit (DIC) of FIG. 1 separated from the display panel (DP), and the driver integrated circuit (DIC) may be connected to the wiring disposed in the non-display area (NDA). However, embodiments are not necessarily limited thereto, and the gate driver 120 may be implemented as an integrated circuit separated from the display panel (DP), together with the data driver 130, the voltage generator 140, and the controller 150.

The display area (DA) may have various shapes. The display area (DA) may have a closed-loop shape including straight and/or curved sides in a plan view. For example, the display area (DA) may have shapes such as a polygon, a circle, a semicircle, or an ellipse.

The display panel (DP) may have a flat display surface. However, embodiments are not necessarily limited thereto, and the display panel (DP) may have a display surface which is at least in part round. The display panel (DP) may be bendable, foldable, or rollable, and the display panel (DP) and/or a substrate of the display panel (DP) may include a material having flexible properties.

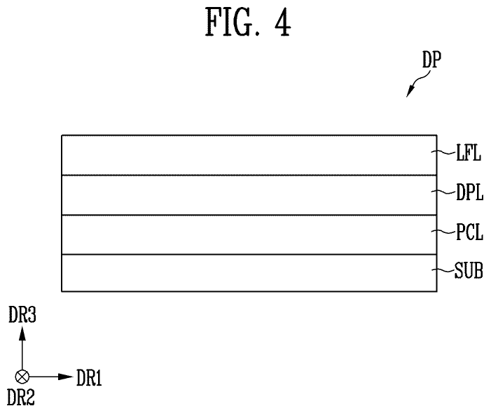

FIG. 4 is a schematic cross-sectional view of a display panel according to an embodiment.

Referring to FIG. 4, the display panel (DP) may include a substrate (SUB), a pixel circuit layer (PCL), a display element layer (DPL), and a light functional layer (LFL) which are sequentially stacked on the substrate (SUB) in a third direction (DR3) intersecting the first and second directions (DR1, DR2).

The substrate (SUB) may be formed of an insulating material such as glass or resin. For example, the substrate (SUB) may include a glass substrate. However, embodiments are not necessarily limited thereto, and the substrate (SUB) may include a polyimide (PI) substrate or a silicon wafer substrate formed using a semiconductor process.

The substrate (SUB) may be formed of a flexible material that is bendable or foldable, and may have a single-layer structure or a multi-layer structure. For example, the substrate (SUB) may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not necessarily limited thereto.

The pixel circuit layer (PCL) may be disposed on the substrate (SUB). The pixel circuit layer (PCL) may include insulation layers and semiconductor patterns and conductive patterns disposed between the insulation layers. The conductive patterns of the pixel circuit layer (PCL) may function as circuit elements, wiring, and so on.

The circuit elements of the pixel circuit layer (PCL) may include the sub-pixel circuit (SPC, see FIG. 2) of each of the sub-pixels (SP) of FIG. 3. In other words, the circuit elements of the pixel circuit layer (PCL) may be provided as transistors and one or more capacitors of the sub-pixel circuit (SPC).

The wiring of the pixel circuit layer (PCL) may include wiring connected to the sub-pixels (SP). The wiring of the pixel circuit layer (PCL) may include various signal lines and/or voltage lines required to drive the display element layer (DPL).

The display element layer (DPL) may be disposed on the pixel circuit layer (PCL). The display element layer (DPL) may include light-emitting elements of the sub-pixels (SP).

The light functional layer (LFL) may be disposed on the display element layer (DPL). The light functional layer (LFL) may include light conversion patterns having color conversion particles and/or scattering particles. For example, the color conversion particles may include quantum dots. The quantum dots may change a wavelength (or color) of the light emitted from the display element layer (DPL). The light functional layer (LFL) may further include light scattering patterns having scattering particles. However, embodiments are not necessarily limited thereto, and the light conversion patterns and the light scattering patterns may be omitted.

The light functional layer (LFL) may further include a color filter layer including color filters. The color filter may selectively transmit light of a specific wavelength (or, a specific color). However, embodiments are not necessarily limited thereto, and the color filter layer may be omitted.

Although not illustrated, a window for protecting the exposed surface (or the top surface) of the display panel (DP) may be provided on the light functional layer (LFL). The window may protect the display panel (DP) from an external impact. The window may be coupled to the light functional layer (LFL) through an optically transparent adhesive (or gluing) member. The window may have a multi-layer structure including a glass substrate, a plastic film, or a plastic substrate. This multi-layered structure may be formed through a continuous process or an adhesion process using an adhesive layer. All or a part of the window may be flexible.

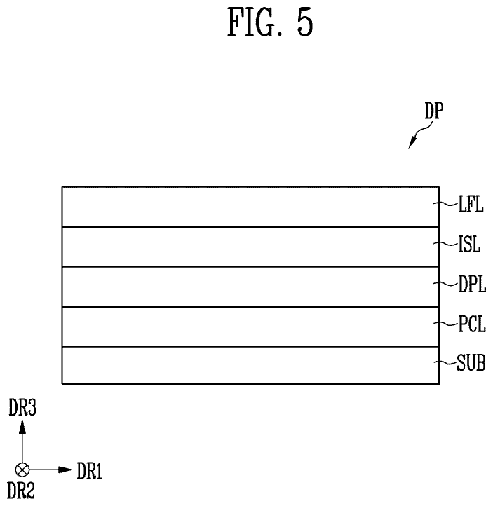

FIG. 5 is a schematic cross-sectional view of a display panel according to an embodiment.

Referring to FIG. 5, the display panel (DP) may include a substrate (SUB), a pixel circuit layer (PCL), a display element layer (DPL), an input-sensing layer (ISL), and a light functional layer (LFL). The substrate (SUB), the pixel circuit layer (PCL), the display element layer (DPL), and the light functional layer (LFL) are configured in the same manner as the substrate (SUB), the pixel circuit layer (PCL), the display element layer (DPL), and the light functional layer (LFL) described in reference to FIG. 4. Hereafter, redundant explanation is omitted.

The input-sensing layer (ISL) may detect a user input to the top surface (or the display surface) of the display panel (DP). The input-sensing layer (ISL) may include configurations appropriate for detecting an external object such as a user's hand or a pen. For example, the input-sensing layer (ISL) may include touch electrodes.

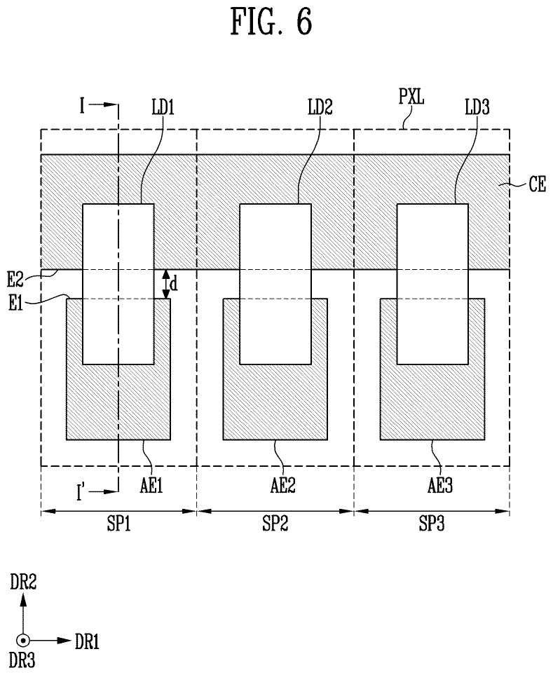

FIG. 6 is a plan view of a pixel according to the embodiment.

Referring to FIG. 6, the pixel (PXL) may include first through third sub-pixels (SP1˜SP3). The first through third sub-pixels (SP1˜SP3) may be arranged in the first direction (DR1). However, embodiments are not necessarily limited thereto. For example, the first through third sub-pixels (SP1˜SP3) may be arranged in zigzag.

First through third anodes (AE1˜AE3) may be disposed in the first through third sub-pixels (SP1˜SP3) respectively. The first anode (AE1) may be provided as an anode (AE, see FIG. 2) connected to the sub-pixel circuit (SPC, see FIG. 2) of the first sub-pixel (SP1). The second anode (AE2) may be provided as an anode (AE) connected to the sub-pixel circuit (SPC) of the second sub-pixel (SP2). The third anode (AE3) may be provided as an anode (AE) connected to the sub-pixel circuit (SPC) of the third sub-pixel (SP3). The first through third anodes (AE1˜AE3) may be spaced apart from the cathode (CE). For example, the first through third anodes (AE1˜AE3) may be spaced apart from the cathode (CE) by a first gap (d) in the second direction (DR2). Edges (E1) of the first through third anodes (AE1˜AE3) facing the cathode (CE) may be in a straight line.

An edge (E2) of the cathode (CE) facing the first through third anodes (AE1˜AE3) may be in a straight line. The cathode (CE) and the first through third anodes (AE1˜AE3) may be disposed at a same height. The cathode (CE) may be extended in the first direction (DR1), and used as a common electrode for the pixel (PXL) and other adjacent pixels. The cathode (CE) may be extended in the second direction (DR2) as well as the first direction (DR1), and used as a common electrode for all of the sub-pixels (SP) of FIG. 3. As such, the cathode (CE) may have various shapes in a plan view.

First through third light-emitting elements (LD1˜LD3) may be disposed on the first through third anodes (AE1˜AE3) and the cathode (CE). The first light-emitting element (LD1) may be electrically connected to the first anode (AE1) and the cathode (CE). The first light-emitting element (LD1) may be provided as a light-emitting element (LD, see FIG. 2) connected to the sub-pixel circuit (SPC) of the first sub-pixel (SP1). The second light-emitting element (LD2) may be electrically connected to the second anode (AE2) and the cathode (CE). The second light-emitting element (LD2) may be provided as a light-emitting element (LD) connected to the sub-pixel circuit (SPC) of the second sub-pixel (SP2). The third light-emitting element (LD3) may be electrically connected to the third anode (AE3) and the cathode (CE). The third light-emitting element (LD3) may be provided as a light-emitting element (LD) connected to the sub-pixel circuit (SPC) of the third sub-pixel (SP3).

The first light-emitting element (LD1), the second light-emitting element (LD2), and the third light-emitting element (LD3) may be inorganic light-emitting diodes including an inorganic light-emitting material. However, embodiments are not necessarily limited thereto, and in another embodiment, the first light-emitting element (LD1), the second light-emitting element (LD2), and the third light-emitting element (LD3) may be organic light-emitting diodes including an organic light-emitting material.

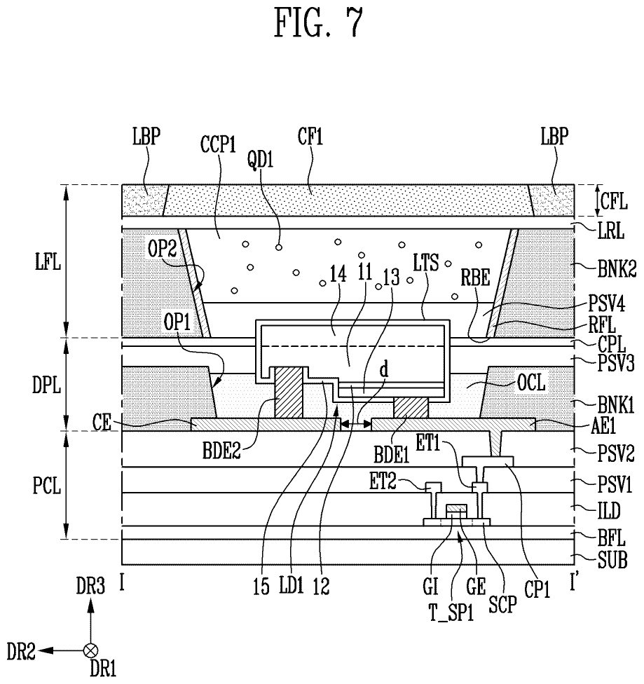

FIG. 7 is a schematic cross-sectional view taken along line I-I′ of FIG. 6.

Referring to FIG. 6 and FIG. 7, the pixel circuit layer (PCL), the display element layer (DPL), and the light functional layer (LFL) may be sequentially arranged on the substrate (SUB).

The pixel circuit layer (PCL) may include insulation layers, semiconductor patterns, and conductive patterns stacked on the substrate (SUB). The insulation layers may include a buffer layer (BFL), one or more interlayer insulation layers (ILD), and one or more passivation layers (PSV1, PSV2). The semiconductor patterns and the conductive patterns may be positioned between the insulation layers. The conductive patterns may include at least one of copper (Cu), molybdenum (Mo), tungsten (W), aluminum neodymium (AlNd), titanium (Ti), aluminum (Al), and silver (Ag).

As described in reference to FIG. 2, the sub-pixel circuit (SPC, see FIG. 2) of each of the first through third sub-pixels (SP1˜SP3) may include transistors and one or more capacitors. The semiconductor patterns and the conductive patterns of the pixel circuit layer (PCL) may function as transistors and capacitors of the sub-pixel circuit (SPC). The conductive patterns of the pixel circuit layer (PCL) may further function as wiring, for example, the first through m-th gate lines (GL1˜GLm), the first through n-th data lines (DL1˜DLn), the power lines (PL), and the pixel control lines (PXCL) of FIG. 1.

The buffer layer (BFL) may be disposed on a surface of the substrate (SUB). The buffer layer (BFL) may prevent impurities from diffusing to the circuit elements and the wiring included in the pixel circuit layer (PCL). The buffer layer (BFL) may include an inorganic insulation layer including an inorganic material. For example, the buffer layer (BFL) may include at least one of silicon nitride (SiNₓ), silicon oxide (SiOₓ), silicon oxynitride (SiOₓN_{y}), and a metal oxide such as aluminum oxide (AlOₓ). The buffer layer (BFL) may be provided as a single layer or a multi-layer. If the buffer layer (BFL) includes multiple layers, each layer may be formed of a same material or different materials.

One or more barrier layers may be disposed between the substrate (SUB) and the buffer layer (BFL). Each of the barrier layers may include a polyimide.

A transistor (T_SP1) may be disposed on the buffer layer (BFL). The transistor (T_SP1) may be one of the transistors of the sub-pixel circuit (SPC) included in the first sub-pixel (SP1). For example, the transistor (T_SP1) may be a transistor connected to the first anode (AE1) among the transistors of the sub-pixel circuit (SPC).

The transistor (T_SP1) may include a semiconductor pattern (SCP), a gate electrode (GE), a first terminal (ET1), and a second terminal (ET2). The first terminal (ET1) may be one of a source electrode and a drain electrode, and the second terminal (ET2) may be another one of the source electrode and the drain electrode. For example, the first terminal (ET1) may be the source electrode, and the second terminal (ET2) may be the drain electrode.

The semiconductor pattern (SCP) may be disposed on the buffer layer (BFL). The semiconductor pattern (SCP) may include a first contact area which contacts the first terminal (ET1) and a second contact area which contacts the second terminal (ET2). An area between the first contact area and the second contact area may be a channel area. The channel area may overlap the gate electrode (GE) of the transistor (T_SP1) in a thickness direction (for example, third direction DR3). The channel area may be a semiconductor pattern not doped with impurities, and may be an intrinsic semiconductor. The first contact area and the second contact area may be a semiconductor pattern doped with impurities. For example, p-type impurities may be used as the impurities, but embodiments are not necessarily limited thereto.

The semiconductor pattern (SCP) may include one of various semiconductors, for example, one of an amorphous silicon semiconductor, a monocrystalline silicon semiconductor, a polycrystalline silicon semiconductor, a low-temperature polysilicon semiconductor, and an oxide semiconductor.

The interlayer insulation layers (ILD) sequentially stacked may be disposed on the semiconductor pattern (SCP). The interlayer insulation layers (ILD) may be inorganic insulation layers including an inorganic material. For example, the interlayer insulation layers (ILD) each may include at least one of silicon nitride (SiNₓ), silicon oxide (SiOₓ), silicon oxynitride (SiOₓN_{y}), and a metal oxide such as aluminum oxide (AlOₓ). However, embodiments are not necessarily limited thereto. For example, one of the interlayer insulation layers (ILD) may include an organic insulation layer including an organic material.

The interlayer insulation layers (ILD) may electrically isolate the conductive patterns and/or the semiconductor patterns disposed between the interlayer insulation layers (ILD). For example, the interlayer insulation layers (ILD) may include a gate insulation layer (GI) disposed on the semiconductor pattern (SCP). The gate insulation layer (GI) may be disposed between the semiconductor pattern (SCP) and the gate electrode (GE), to make the gate electrode (GE) spaced away from the semiconductor pattern (SCP). The gate insulation layer (GI) may be provided entirely on the semiconductor pattern (SCP) and the buffer layer (BFL), to cover the semiconductor pattern (SCP) and the buffer layer (BFL). As the number of layers required for forming the conductive patterns and/or the semiconductor patterns increases, the number of the interlayer insulation layers (ILD) may increase.

The gate electrode (GE) may be disposed on the gate insulation layer (GI). The gate electrode (GE) may overlap the channel area of the semiconductor pattern (SCP) in a thickness direction. The gate electrode (GE) may be provided as a single layer including at least one of copper (Cu), molybdenum (Mo), tungsten (W), aluminum neodymium (AlNd), titanium (Ti), aluminum (Al), and silver (Ag). However, embodiments are not necessarily limited thereto. For example, the gate electrode (GE) may have a multi-layer structure including at least one of molybdenum (Mo), titanium (Ti), copper (Cu), aluminum (Al), and silver (Ag) which are low-resistance materials.

The first and second terminals (ET1, ET2) may be disposed on the interlayer insulation layers (ILD). The first and second terminals (ET1 and ET2) may contact the semiconductor pattern (SCP) through contact holes which penetrate the interlayer insulation layers (ILD). The first and second terminals (ET1 and ET2) may contact the first and second contact areas of the semiconductor pattern (SCP) respectively. Each of the first and second terminals (ET1, ET2) may include at least one of copper (Cu), molybdenum (Mo), tungsten (W), aluminum neodymium (AlNd), titanium (Ti), aluminum (Al), and silver (Ag).

The first and second terminals (ET1, ET2) are depicted as separate electrodes electrically connected to the semiconductor pattern (SCP), but embodiments are not necessarily limited thereto. The first terminal (ET1) may be the first contact area adjacent to a side of the channel area of the semiconductor pattern (SCP), the second terminal (ET2) may be the second contact area adjacent to another side of the channel area, and the first terminal (ET1) may be electrically connected to the first light-emitting element (LD1) through connection means such as a bridge electrode disposed on at least one of the interlayer insulation layers (ILD).

The transistor (T_SP1) may include a low-temperature polysilicon transistor. However, embodiments are not necessarily limited thereto. For example, the transistor (T_SP1) may include an oxide semiconductor transistor. The sub-pixel circuit of the first sub-pixel (SP1) may include different types of transistors. For example, the transistor (T_SP1) may include a low-temperature polysilicon transistor, and another transistor of the first sub-pixel (SP1) may include an oxide semiconductor transistor. The oxide semiconductor of the corresponding oxide semiconductor transistor may be disposed on one of the interlayer insulation layers (ILD), rather than the insulation layer in which the semiconductor pattern (SCP) of the transistor (T_SP1) is disposed.

Although an embodiment that the transistor (T_SP1) is a transistor of a top gate structure is described, embodiments are not necessarily limited thereto. For example, the transistor (T_SP1) may be a transistor of a bottom gate structure. For example, the structure of the transistor (T_SP1) may be variously changed.

At least a part of the various wiring of the display panel (DP) and/or the display device (DD) may be disposed on the interlayer insulation layers (ILD).

A first passivation layer (PSV1) may be disposed on the interlayer insulation layers (ILD) and the first and second terminals (ET1, ET2). The passivation layer may be referred to as a protective layer or a via layer. The first passivation layer (PSV1) may protect the components disposed underneath the first passivation layer (PSV1), and provide a flat top surface.

A connection pattern (CP1) may be disposed on the first passivation layer (PSV1). The connection pattern (CP1) may penetrate the first passivation layer (PSV1) and connect to the first terminal (ET1) of the transistor (T_SP1). The connection pattern (CP1) may include at least one of copper (Cu), molybdenum (Mo), tungsten (W), aluminum neodymium (AlNd), titanium (Ti), aluminum (Al), and silver (Ag).

At least a part of the various wiring of the display panel (DP) and/or the display device (DD) may be disposed on the first passivation layer (PSV1).

A second passivation layer (PSV2) may be disposed on the connection pattern (CP1) and the first passivation layer (PSV1). The second passivation layer (PSV2) may protect the components disposed underneath the second passivation layer (PSV2), and provide a flat top surface.

The first and second passivation layers (PSV1, PSV2) each may include an inorganic insulation layer including an inorganic material and/or an organic insulation layer including an organic material. For example, the inorganic insulation layer may include at least one of silicon oxide (SiOₓ), silicon nitride (SiNₓ), silicon oxynitride (SiOₓN_{y}), and a metal oxide such as aluminum oxide (AlOₓ). For example, the organic insulation layer may include at least one of an acrylic resin, an epoxy resin, a phenol resin, a polyamide resin, a polyimide resin, an unsaturated polyester resin, a poly-phenylene ether resin, a poly-phenylene sulfide resin, and a benzocyclobutene resin.

The first and second passivation layers (PSV1, PSV2) and one of the interlayer insulation layers (ILD) may include a same material, but embodiments are not necessarily limited thereto. Each of the first and second passivation layers (PSV1, PSV2) may be provided as a single layer, or multi-layers.

The display element layer (DPL) may be disposed on the second passivation layer (PSV2). The display element layer (DPL) may include a first anode (AE1), a cathode (CE), a first bank (BNK1), a first light-emitting element (LD1), an overcoat layer (OCL), a third passivation layer (PSV3), and a capping layer (CPL).

The first anode (AE1) and the cathode (CE) may be disposed on the pixel circuit layer (PCL). The first anode (AE1) may be electrically connected to the connection pattern (CP1) via a contact hole penetrating the second passivation layer (PSV2). As such, the first anode (AE1) may be electrically connected to the first transistor (T_SP1). The cathode (CE) may be spaced apart from the first anode (AE1) by the first gap (d) in the second direction (DR2). The cathode (CE) may be electrically connected to the second power voltage node (VSSN) of FIG. 2. Hence, the second power voltage applied to the second power voltage node (VSSN) may be transmitted to the cathode (CE).

The first bank (BNK1) may be disposed on the first anode (AE1) and the cathode (CE). The first bank (BNK1) may have a first opening (OP1) for exposing parts of the first anode (AE1) and the cathode (CE). The first light-emitting element (LD1) may be disposed in the first opening (OP1) of the first bank (BNK1). As such, the first bank (BNK1) may be provided as a pixel-defining layer for defining the area in which the first light-emitting element (LD1) is positioned.

The first bank (BNK1) may include a light blocking material, to prevent light mixing between adjacent sub-pixels. The first bank (BNK1) may include an organic material. For example, the first bank (BNK1) may include an organic insulating material such as an acrylic resin, an epoxy resin, a phenol resin, a polyamide resin, and a polyimide resin. However, embodiments are not necessarily limited thereto.

The first light-emitting element (LD1) may be electrically connected to the first anode (AE1). The first light-emitting element (LD1) may be electrically connected to the cathode (CE). The first light-emitting element (LD1) may be coupled to the first anode (AE1) and the cathode (CE) by bonding. For example, the first light-emitting element (LD1) may be coupled to the first anode (AE1) and the cathode (CE) by eutectic bonding.

The first light-emitting element (LD1) may include a first semiconductor layer 11, an active layer 12, a second semiconductor layer 13, and an auxiliary layer 14. The first light-emitting element (LD1) may include an emissive stack in which the auxiliary layer 14, the first semiconductor layer 11, the active layer 12, and the second semiconductor layer 13 are sequentially stacked.

The first light-emitting element (LD1) may include first and second bonding electrodes (BDE1, BDE2) facing in a same direction (e.g., an opposite direction to the third direction (DR3)). The first bonding electrode (BDE1) may be connected to the second semiconductor layer 13. The second bonding electrode (BDE2) may be connected to the first semiconductor layer 11 exposed by etching the second semiconductor layer 13 and the active layer 12. The first light-emitting element (LD1) may be a flip-chip type light-emitting element.

The first semiconductor layer 11 may provide electrons to the active layer 12. For example, the first semiconductor layer 11 may include at least one n-type semiconductor layer. For example, the first semiconductor layer 11 may include at least one of gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or an n-type dopant) such as silicon (Si), germanium (Ge), or tin (Sn). However, the material configuring the first semiconductor layer 11 is not necessarily limited thereto, and various other materials may configure the first semiconductor layer 11.

The active layer 12 may be disposed on the first semiconductor layer 11, and may be an area where electrons and holes are recombined. As the electrons and the holes recombine in the active layer 12, light having a corresponding wavelength may be generated by transferring to a lower energy level. The active layer 12 may be formed in a single or multi-quantum well structure. If the active layer 12 is formed in the multi-quantum well structure, a unit including a barrier layer, a strain reinforcing layer, and a well layer may be repeatedly stacked each other to form the active layer 12. However, embodiments are not necessarily limited thereto.

The second semiconductor layer 13 may be disposed on the active layer 12, to provide holes to the active layer 12. The second semiconductor layer 13 may include a semiconductor layer of a different type from the first semiconductor layer 11. For example, the second semiconductor layer 13 may include at least one p-type semiconductor layer. For example, the second semiconductor layer 13 may include at least one of gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or a p-type dopant) such as magnesium (Mg), zinc (Zn), calcium (Ca), strontium (Sr), or barium (Ba). However, the material configuring the second semiconductor layer 13 is not necessarily limited thereto, and various other materials may configure the second semiconductor layer 13.

The auxiliary layer 14 may include gallium nitride (GaN) not doped with impurities, and may configure the n-type semiconductor layer together with the first semiconductor layer 11.

The first bonding electrode (BDE1) may be electrically connected to the second semiconductor layer 13. The second bonding electrode (BDE2) may be electrically connected to the first semiconductor layer 11. The first and second bonding electrodes (BDE1, BDE2) may include a eutectic metal.

The first light-emitting element (LD1) may further include an insulation film 15 for covering an outer peripheral surface of the emissive stack. The insulation film 15 may prevent electrical short circuiting which may occur if the active layer 12 contacts other conductive material than the first and second semiconductor layers 11 and 13. The insulation film 15 may include a transparent insulating material. The insulation film 15 may be configured to expose lower surfaces of the first and second bonding electrodes (BDE1, BDE2).

The lower surface of the first bonding electrode (BDE1) may contact the first anode (AE1). Hence, the first bonding electrode (BDE1) may be electrically connected to the first anode (AE1). The lower surface of the second bonding electrode (BDE2) may contact the cathode (CE). Thus, the second bonding electrode (BDE2) may be electrically connected to the cathode (CE).

The overcoat layer (OCL) may be disposed in the first opening (OP1) where the first light-emitting element (LD1) is disposed. The overcoat layer (OCL) may fix the first light-emitting element (LD1) bonded to the first anode (AE1) and the cathode (CE) not to move. The overcoat layer (OCL) may protect the components disposed underneath the overcoat layer (OCL) from a foreign substance such as dust or moisture. For example, the overcoat layer (OCL) may include at least one of an inorganic insulation layer and an organic insulation layer. For example, the overcoat layer (OCL) may include an epoxy, but embodiments are not necessarily limited thereto.

The third passivation layer (PSV3) may be disposed on the first bank (BNK1) and the overcoat layer (OCL). The third passivation layer (PSV3) may protect the components disposed underneath the third passivation layer (PSV3), and provide a flat top surface. The third passivation layer (PSV3) and one of the first and second passivation layers (PSV1, PSV2) may include a same material, but embodiments are not necessarily limited thereto.

The third passivation layer (PSV3) may not be disposed on the top surface (LTS) of the first light-emitting element (LD1). The first light-emitting element (LD1) may be protruded to the light functional layer (LFL). The first light-emitting element (LD1) may be positioned at least in part in the second opening (OP2) of the second bank (BNK2). For example, a top surface (LTS) of the first light-emitting element (LD1) from the substrate (SUB) may be higher than a lowest end (RBE) of a reflective layer (RFL). Hence, the light emitted from the first light-emitting element (LD1) may be provided to the light functional layer (LFL) at a relatively high rate.

The capping layer (CPL) may be disposed on the third passivation layer (PSV3). The capping layer (CPL) may protect the components below the capping layer (CPL), such as the first light-emitting element (LD1), from external moisture and humidity. The capping layer (CPL) may not be disposed on the top surface of the first light-emitting element (LD1). However, embodiments are not necessarily limited thereto. For example, the capping layer (CPL) may entirely cover the first light-emitting element (LD1) and the third passivation layer (PSV3). The capping layer (CPL) may include at least one of silicon nitride (SiNₓ), silicon oxide (SiOₓ), silicon oxynitride (SiOₓN_{y}), and a metal oxide such as aluminum oxide (AlOₓ), but embodiments are not necessarily limited thereto.

So far, the pixel circuit layer (PCL) and the display element layer (DPL) of the first sub-pixel (SP1) have been described. Each of the second and third sub-pixels (SP2, SP3) of FIG. 6 may be configured in the same manner as the first sub-pixel (SP1), unless otherwise described herein.

The light functional layer (LFL) may be disposed on the capping layer (CPL). The light functional layer (LFL) may include a second bank (BNK2), a reflective layer (RFL), a fourth passivation layer (PSV4), a first light conversion pattern (CCP1), a low refractive layer (LRL), and a color filter layer (CFL).

The second bank (BNK2) may be disposed on the capping layer (CPL). The second bank (BNK2) may overlap the first bank (BNK1) in the thickness direction. The second bank (BNK2) may have a second opening (OP2) which overlaps the first opening (OP1) in the thickness direction.

The second bank (BNK2) may include a light blocking material, to prevent light mixing between adjacent sub-pixels. The second bank (BNK2) may include an organic material. For example, the second bank (BNK2) may include an organic insulating material such as an acrylic resin, an epoxy resin, a phenol resin, a polyamide resin, and a polyimide resin. However, embodiments are not necessarily limited thereto.

The reflective layer (RFL) may be disposed on the sides of the second bank (BNK2) adjacent to the second opening (OP2). The reflective layer (RFL) may be configured to reflect the incident light, to thus improve emission efficiency. The reflective layer (RFL) may include an appropriate material for reflecting the light. For example, the reflective layer (RFL) may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy thereof. However, embodiments are not necessarily limited thereto.

The fourth passivation layer (PSV4) may be disposed in the second opening (OP2) on the capping layer (CPL). The fourth passivation layer (PSV4) may protect the components disposed underneath the fourth passivation layer (PSV4), and provide a flat top surface. The fourth passivation layer (PSV4) and one of the first through third passivation layers (PSV1˜PSV3) may include a same material, but embodiments are not necessarily limited thereto.

The first light conversion pattern (CCP1) may be disposed in the second opening (OP2) on the fourth passivation layer (PSV4).

The first light conversion pattern (CCP1) may include color conversion particles and/or scattering particles. The color conversion particles may convert the incident light into light of a different color by changing the wavelength of the incident light. The color conversion particles may also scatter the incident light. The color conversion particles may be quantum dots. The scattering particles may scatter the incident light.

The first sub-pixel (SP1) may be a red sub-pixel. If the first light-emitting element (LD1) emits blue-colored light, the first light conversion pattern (CCP1) may include first color conversion particles (QD1) configured to convert the blue-colored light into red-colored light. If the first light-emitting element (LD1) emits red-colored light, the first light conversion pattern (CCP1) may include scattering particles. As such, the particles included in the first light conversion pattern (CCP1) may vary depending on the first light-emitting element (LD1).

The low refractive layer (LRL) may be disposed on the second bank (BNK2), the reflective layer (RFL), and the first light conversion pattern (CCP1). The low refractive layer (LRL) may have a refractive index lower than the first light conversion pattern (CCP1). The low refractive layer (LRL) may be configured to refract or totally reflect the corresponding light according to an incident angle of the light. For example, the low refractive layer (LRL) may provide the light passing through the first light conversion pattern (CCP1) back to the first light conversion pattern (CCP1). Hence, light conversion efficiency of the first light conversion pattern (CCP1) may be improved.

The color filter layer (CFL) may be disposed on the low refractive layer (LRL). The color filter layer (CFL) may include a first color filter (CF1) and light blocking patterns (LBP). The first color filter (CF1) may overlap the first light conversion pattern (CCP1) in the thickness direction. The first color filter (CF1) may selectively transmit light in a desired wavelength range. If the first sub-pixel (SP1) is a red sub-pixel, the first color filter (CF1) may include a red color filter. The light blocking patterns (LBP) may include at least one light blocking material.

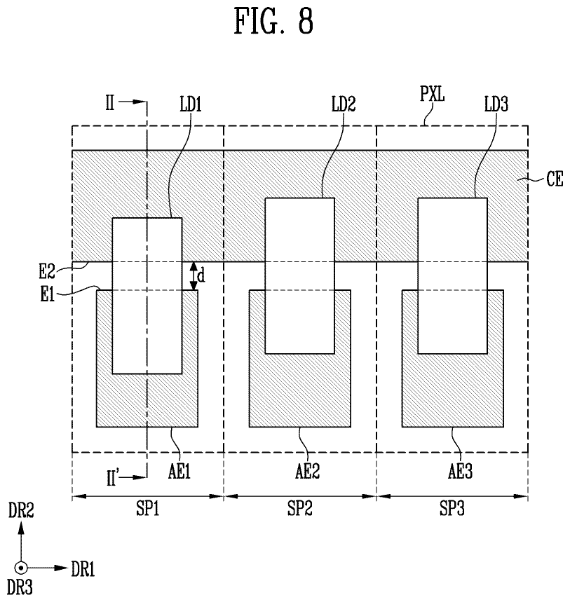

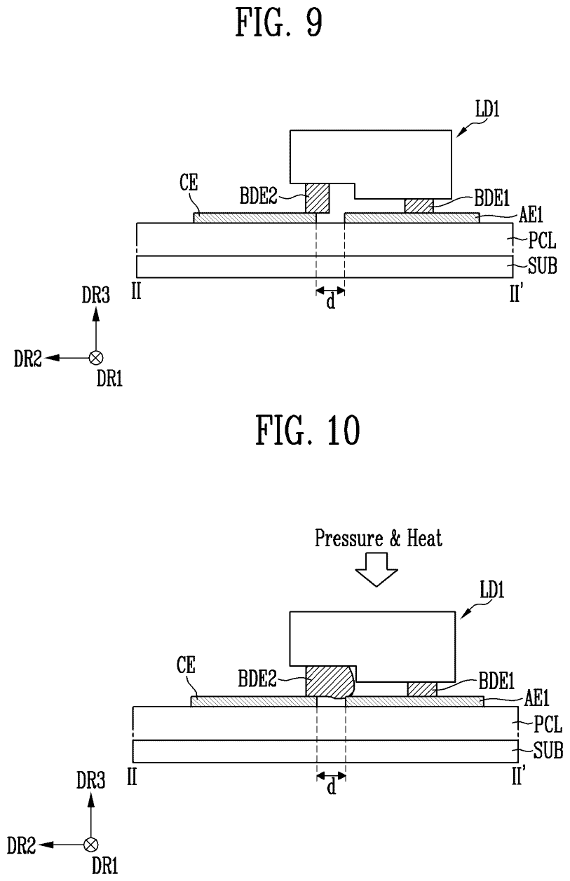

FIG. 8 is a plan view illustrating misalignment of a light-emitting element. FIG. 9 is a schematic cross-sectional view taken along line II-II′ of FIG. 8. FIG. 10 is a schematic cross-sectional view illustrating a contact failure due to misalignment of a light-emitting element. For ease of explanation, FIG. 9 and FIG. 10 briefly illustrate some of the configurations shown in FIG. 7.

Referring to FIG. 8 and FIG. 9, a manufacturing process of the display device (DD, see FIG. 1) having a high resolution over 300 pixel per inch (ppi) may have an insufficient alignment margin, and misalignment of the light-emitting element may occur. For example, because the first gap (d) between the first anode (AE1) and the cathode (CE) is narrow due to a design structure corresponding to the high resolution, the first light-emitting element (LD1) may be bonded to other position than a target position. For example, the alignment position of the first light-emitting element (LD1) may not coincide with the alignment positions of the second and third light-emitting elements (LD2, LD3). As shown in FIG. 9, the second bonding electrode (BDE2) of the first light-emitting element (LD1) may be positioned in the gap between the first anode (AE1) and the cathode (CE).

Referring to FIG. 10, the first light-emitting element (LD1) may be bonded to the first anode (AE1) and the cathode (CE) by applying pressure and heat. For example, the first bonding electrode (BDE1) may be bonded to the first anode (AE1) by eutectic bonding, and the second bonding electrode (BDE2) may be bonded to the cathode (CE) by eutectic bonding. In the bonding process, phases of the first and second bonding electrodes (BDE1, BDE2) may be transferred to a liquid phase by pressure and heat. Due to the misalignment of the first light-emitting element (LD1) and the narrow first gap (d) between the cathode (CE) and the first anode (AE1), the second bonding electrode (BDE2) in the liquid state may diffuse to cause a short circuit failure bonded to the first anode (AE1).

FIG. 8 to FIG. 10 schematically illustrate the short circuit failure caused if the first light-emitting element (LD1) is misaligned in the opposite direction of the second direction (DR2), but embodiments are not necessarily limited thereto. For example, the first light-emitting element (LD1) may be misaligned in the second direction (DR2), and a short circuit failure in which the first bonding electrode (BDE1) in the liquid state is diffused and bonded to the cathode (CE) may occur.

FIG. 8 to FIG. 10 schematically illustrate the short circuit failure caused by the misalignment of the first light-emitting element (LD1), but embodiments are not necessarily limited thereto. In another embodiment, a short circuit failure may occur due to misalignment of the second light-emitting element (LD2) and/or the third light-emitting element (LD3).

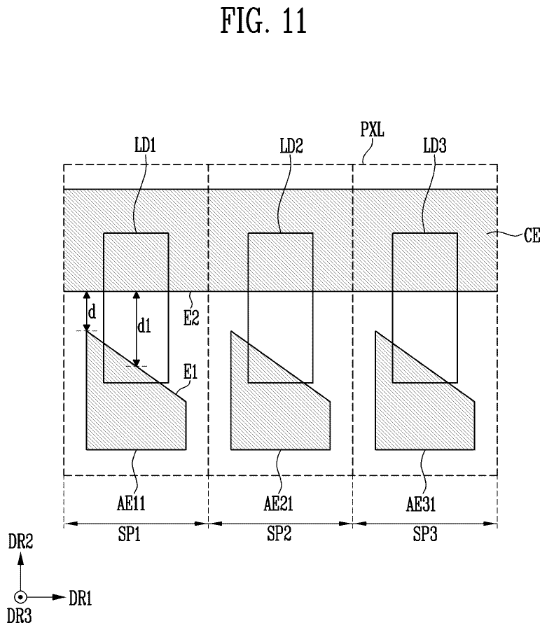

FIG. 11 to FIG. 21 are plan views of a pixel according to embodiments.

Referring to FIG. 11, a first anode (AE11) may be disposed at a position spaced apart from the cathode (CE) by the first gap (d) in the second direction DR2. The edge (E2) of the cathode (CE) facing the first anode (AE11) may be in a straight line. The edge (E1) of the first anode (AE11) facing the cathode (CE) may be diagonal. A second gap (d1) between the first anode (AE11) and the cathode (CE) facing each other may vary along the first direction (DR1). For example, the second gap (d1) may increase along the first direction (DR1). However, embodiments are not necessarily limited thereto. For example, the shape of the first anode (AE11) may be changed to be symmetrical to the shape of FIG. 11, and the second gap (d1) may decrease along the first direction (DR1). The second gap (d1) may be greater than the first gap (d). Due to the wide second gap (d1) between the first anode (AE11) and the cathode (CE) facing each other, alignment accuracy of the first light-emitting element (LD1) may increase. Even if a misalignment of the first light-emitting element (LD1) occurs, the aforementioned short circuit failure may be prevented, because the second gap (d1) is wide.

Compared to FIG. 8, the contact area of the first light-emitting element (LD1) and the first anode (AE11) may be reduced in FIG. 11, but the electrical connection structure may not be impaired, because the first light-emitting element (LD1) is eutectic-bonded to the first anode (AE13).

The second and third anodes (AE21, AE31) each may be configured in the same manner as the first anode (AE11) of FIG. 11 unless otherwise described above.

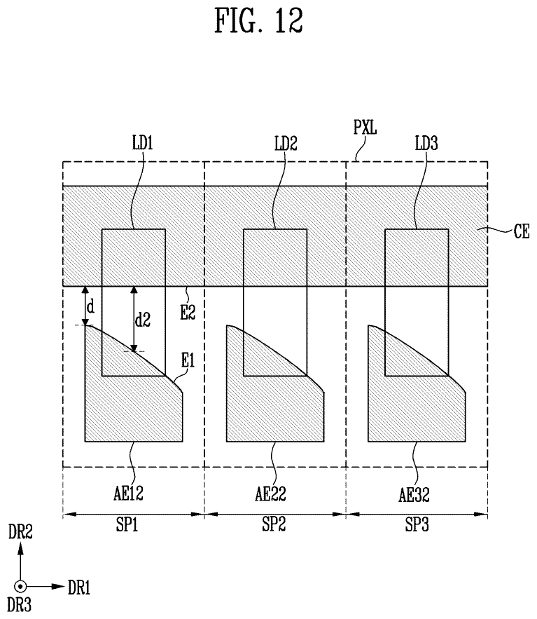

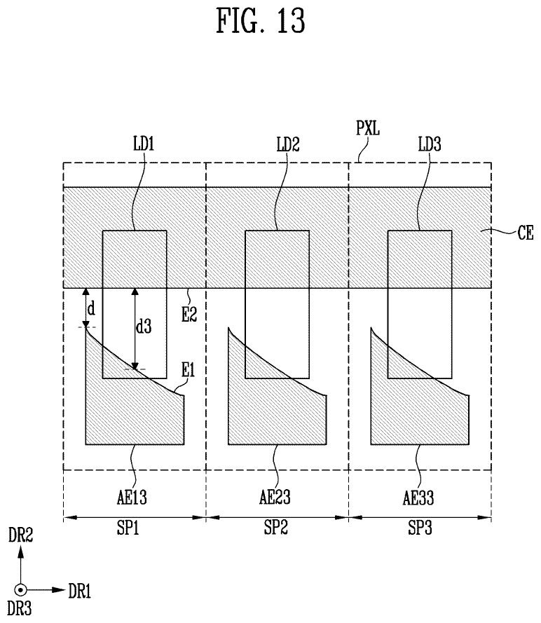

Referring to FIG. 12, the edge (E2) of the cathode (CE) facing the first anode (AE12) may be in a straight line. The edge (E1) of the first anode (AE12) facing the cathode (CE) may be in the form of an upward convex curve. A second gap (d2) between the first anode (AE12) and the cathode (CE) facing each other may be greater than the first gap (d) in the second direction DR2. Due to the wide second gap (d2) between the first anode (AE12) and the cathode (CE) facing each other, the alignment accuracy of the first light-emitting element (LD1) may be increased. Even if a misalignment of the first light-emitting element (LD1) occurs, the aforementioned short circuit failure may be prevented, because the second gap (d2) is wide.

Each of the second and third anodes (AE22, AE32) may be configured in the same manner as the first anode (AE12) of FIG. 12 unless otherwise described above.

Referring to FIG. 13, the edge (E2) of the cathode (CE) facing the first anode (AE13) may be in a straight line. The edge (E1) of the first anode (AE13) facing the cathode (CE) may be in the form of a downward concave curve. A second gap (d3) between the first anode (AE13) and the cathode (CE) facing each other may be greater than the first gap (d). Due to the wide second gap (d3) between the first anode (AE13) and the cathode (CE) facing each other, the alignment accuracy of the first light-emitting element (LD1) may increase. Even if a misalignment of the first light-emitting element (LD1) occurs, the aforementioned short circuit failure may be prevented, because the second gap (d3) is wide.

Each of the second and third anodes (AE23, AE33) may be configured in the same manner as the first anode (AE13) of FIG. 13 unless otherwise described above.

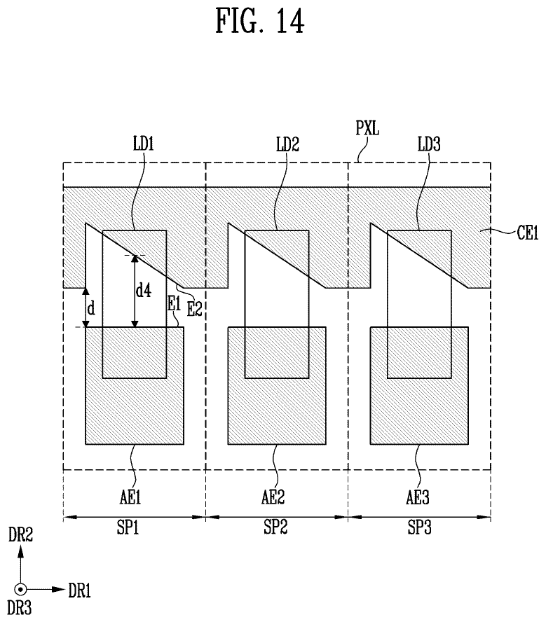

Referring to FIG. 14, the edge (E2) of the cathode (CE1) facing the first anode (AE1) may be diagonal. The edge (E1) of the first anode (AE1) facing the cathode (CE1) may be in a straight line. A second gap (d4) between the first anode (AE1) and the cathode (CE1) facing each other may vary along the first direction (DR1). For example, the second gap (d4) may decrease along the first direction (DR1). However, embodiments are not necessarily limited thereto. For example, the shape of the cathode (CE1) may be changed to be symmetrical to the shape of FIG. 14, and the second gap (d4) may increase along the first direction (DR1). The second gap (d4) may be greater than the first gap (d). Due to the wide second gap (d4) between the first anode (AE1) and the cathode (CE1) facing each other, the alignment accuracy of the first light-emitting element (LD1) may increase. Even if a misalignment of the first light-emitting element (LD1) occurs, the aforementioned short circuit failure may be prevented, because the second gap (d3) is wide.

The edges of the cathode (CE1) facing the second and third anodes (AE2, AE3) respectively may be also configured in the same manner as the edge (E2) of the cathode (CE1) of FIG. 14 unless otherwise described above.

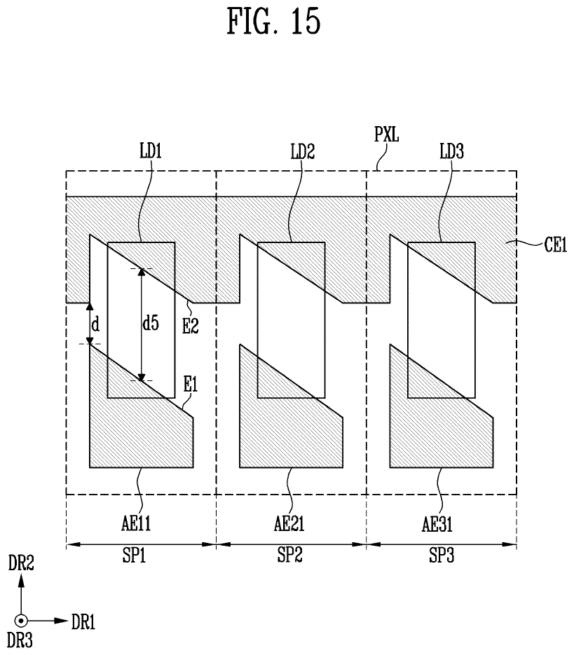

Referring to FIG. 15, the edge (E2) of the cathode (CE1) facing the first anode (AE11) may be diagonal. The edge (E1) of the first anode (AE11) facing the cathode (CE1) may be diagonal. A second gap (d5) between the first anode (AE11) and the cathode (CE1) facing each other may be constant along the first direction (DR1). The second gap (d5) may be greater than the first gap (d). Due to the wider second gap (d5) between the first anode (AE11) and the cathode (CE1) facing each other, the alignment accuracy of the first light-emitting element (LD1) may be further increased. Even if a misalignment of the first light-emitting element (LD1) occurs, the short circuit failure may be prevented more effectively, because the second gap (d5) is far wider.

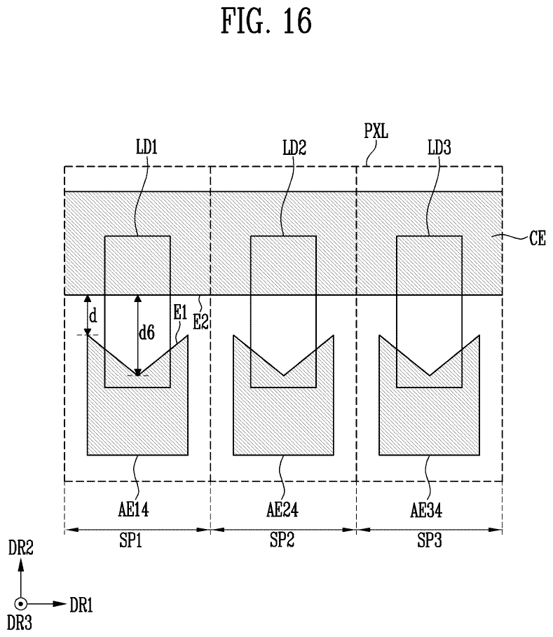

Referring to FIG. 16, the edge (E2) of the cathode (CE) facing the first anode (AE14) may be in a straight line. The edge (E1) of the first anode (AE14) facing the cathode (CE) may be in a V shape. A second gap (d6) between the first anode (AE14) and the cathode (CE) facing each other may increase and decrease along the first direction (DR1). The second gap (d6) may be greater than the first gap (d). Due to the wide second gap (d6) between the first anode (AE14) and the cathode (CE) facing each other, the alignment accuracy of the first light-emitting element (LD1) may increase. Even if a misalignment of the first light-emitting element (LD1) occurs, the aforementioned short circuit failure may be prevented, because the second gap (d6) is wide.

Each of the second and third anodes (AE24, AE34) may be configured in the same manner as the first anode (AE14) of FIG. 16 unless otherwise described above.

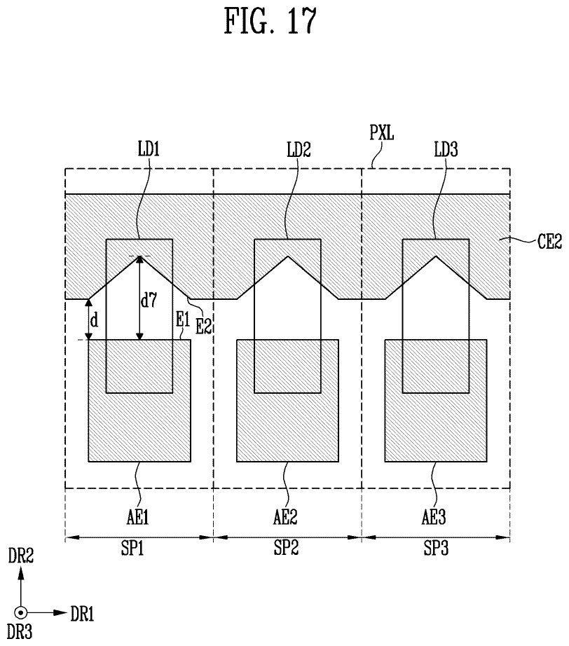

Referring to FIG. 17, the edge (E2) of the cathode (CE2) facing the first anode (AE1) may be in an inverted V shape. The edge (E1) of the first anode (AE1) facing the cathode (CE2) may be in a straight line. A second gap (d7) between the first anode (AE1) and the cathode (CE2) facing each other may increase and decrease along the first direction (DR1). The second gap (d7) may be greater than the first gap (d). Due to the wide second gap (d7) between the first anode (AE1) and the cathode (CE2) facing each other, the alignment accuracy of the first light-emitting element (LD1) may increase. Even if a misalignment of the first light-emitting element (LD1) occurs, the aforementioned short circuit failure may be prevented, because the second gap (d7) is wide.

The edges of the cathode (CE2) facing the second and third anodes (AE2, AE3) respectively may be configured in the same manner as the edge (E2) of the cathode (CE2) of FIG. 17 unless otherwise described above.

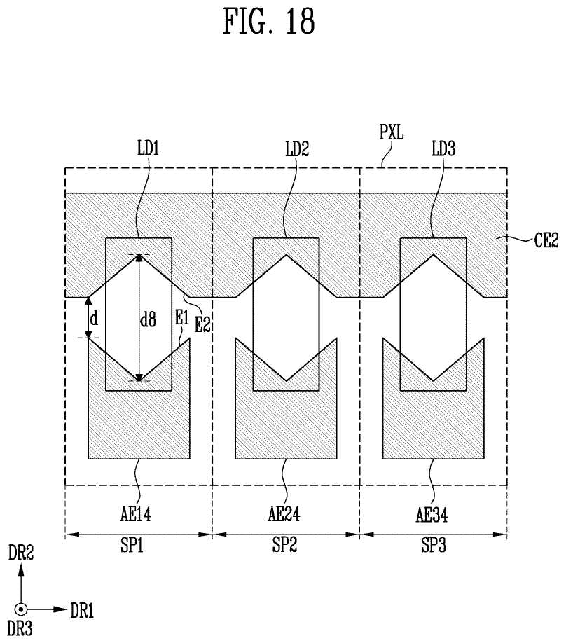

Referring to FIG. 18, the edge (E1) of the first anode (AE14) facing the cathode (CE2) may be V-shaped. The edge of the cathode (CE2) facing the first anode (AE14) may be in an inverted V shape. A second gap (d8) between the first anode (AE14) and the cathode (CE2) facing each other may increase and decrease along the first direction (DR1). The second gap (d8) may be greater than the first gap (d). Due to the wide second gap (d8) between the first anode (AE14) and the cathode (CE2) facing each other, the alignment accuracy of the first light-emitting element (LD1) may increase more. Even if a misalignment of the first light-emitting element (LD1) occurs, the aforementioned short circuit failure may be prevented more effectively, because the second gap (d8) is far wider.

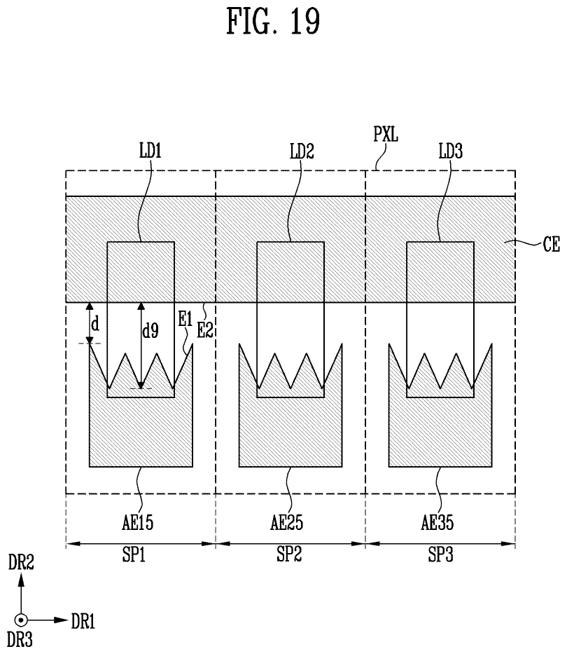

Referring to FIG. 19, the edge (E2) of the cathode (CE) facing the first anode (AE15) may be in a straight line. The edge (E1) of the first anode (AE15) facing the cathode (CE) may be saw-toothed. A second gap (d9) between the first anode (AE15) and the cathode (CE) facing each other may repeatedly increase and decrease along the first direction (DR1). The second gap (d9) may be greater than the first gap (d). Due to the wide second gap (d9) between the first anode (AE15) and the cathode (CE) facing each other, the alignment accuracy of the first light-emitting element (LD1) may increase. Even if a misalignment of the first light-emitting element (LD1) occurs, the aforementioned short circuit failure may be prevented, because the second gap (d9) is wide.

Each of the second and third anodes (AE25, AE35) may be configured in the same manner as the first anode (AE15) of FIG. 19 unless otherwise described above.

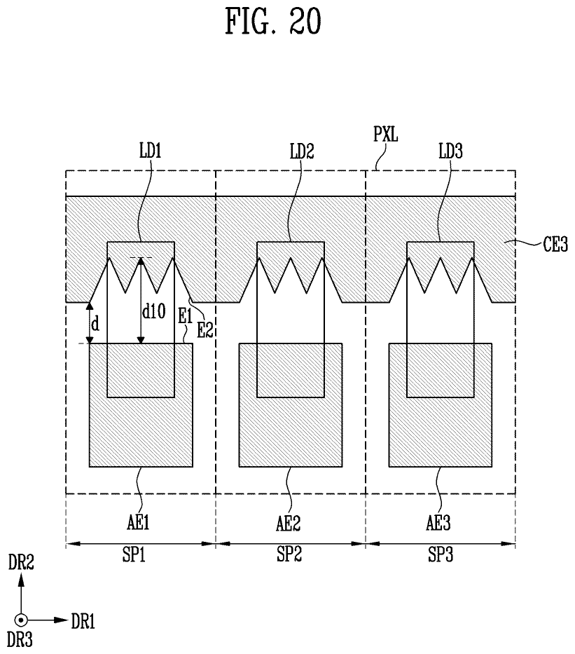

Referring to FIG. 20, the edge (E2) of the cathode (CE3) facing the first anode (AE1) may be saw-toothed. The edge (E1) of the first anode (AE1) facing the cathode (CE3) may be in a straight line. A second gap (d10) between the first anode (AE1) and the cathode (CE3) facing each other may repeatedly increase and decrease along the first direction (DR1). The second gap (d10) may be greater than the first gap (d). Due to the wide second gap (d10) between the first anode (AE1) and the cathode (CE3) facing each other, the alignment accuracy of the first light-emitting element (LD1) may increase. Even if a misalignment of the first light-emitting element (LD1) occurs, the aforementioned short circuit failure may be prevented, because the second gap (d10) is wide.

The edges of the cathode (CE3) facing the second and third anodes (AE2, AE3) respectively may be configured in the same manner as the edge (E2) of the cathode (CE3) of FIG. 20 unless otherwise described above.

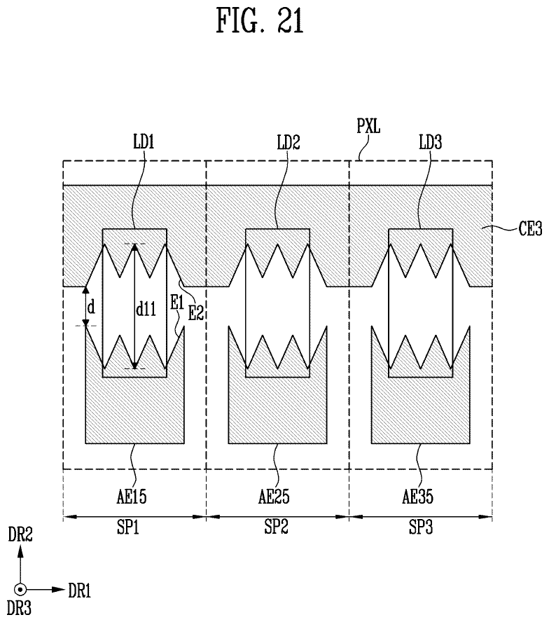

Referring to FIG. 21, the edge (E2) of the cathode (CE3) facing the first anode (AE15) may be saw-toothed. The edge (E1) of the first anode (AE15) facing the cathode (CE3) may be saw-toothed. For example, the edge (E1) of the first anode (AE15) and the edge (E2) of the cathode (CE3) may be symmetrical to each other. A second gap (d11) between the first anode (AE15) and the cathode (CE3) facing each other may repeatedly increase and decrease along the first direction (DR1). The second gap (d11) may be greater than the first gap (d). Due to the wider second gap (d10) between the first anode (AE15) and the cathode (CE3) facing each other, the alignment accuracy of the first light-emitting element (LD1) may increase more. Even if a misalignment of the first light-emitting element (LD1) occurs, the aforementioned short circuit failure may be more effectively prevented, because the second gap (d11) is wider.

As described above, the shapes of the first through third anodes (AE1˜AE3) and/or the cathode (CE) of FIG. 6 may be variously modified to prevent the misalignment and the short circuit failure of the first through third light-emitting elements (LD1˜LD3). In addition to the embodiments shown in FIG. 11 to FIG. 21, a structure in which the gap (or, the second gap) between the first through third anodes (AE1˜AE3) facing each other and the cathode (CE) is greater than the first gap (d) may also be included in the scope of the disclosure.

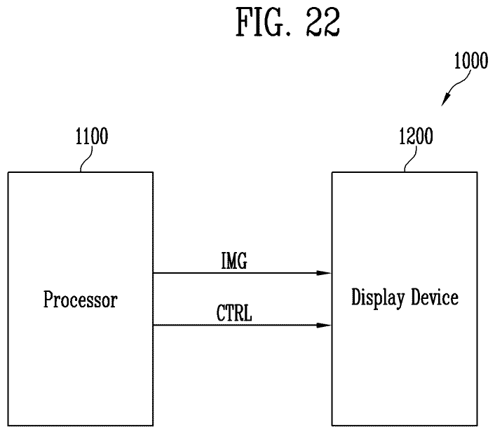

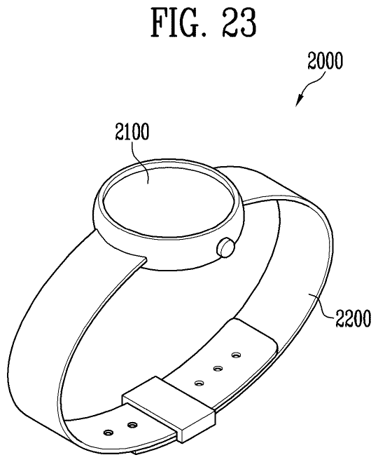

FIG. 22 is a schematic diagram of a display system according to an embodiment.

Referring to FIG. 22, a display system 1000 may include a processor 1100 and a display device 1200.

The processor 1100 may perform various tasks and calculations. In embodiments, the processor 1100 may include an application processor, a graphics processor, a microprocessor, a central processing unit (CPU), and on the like. The processor 1100 may be connected to other components of the display system 1000 via a bus system to control the display device 1200.

The processor 1100 may transmit image data (IMG) and a control signal (CTRL) to the display device 1200. The display device 1200 may display an image based on the image data (IMG) and the control signal (CTRL). The display device 1200 may be configured in the same manner as the display device (DD) described in reference to FIG. 1. The image data (IMG) and the control signal (CTRL) may be provided as the input image data (IMG) and the control signal (CTRL) of FIG. 1 respectively.

The display system 1000 may include a computing system for providing an image display function such as a smart watch, a mobile phone, a smart phone, a portable computer, a tablet personal computer (PC), a watch phone, an automotive display, smart glasses, a portable multimedia player (PMP), navigation, or an ultra mobile personal computer (UMPC). The display system 1000 may include at least one of a head mounted display (HMD), a virtual reality (VR) device, a mixed reality (MR) device, and an augmented reality (AR) device.

FIG. 23 to FIG. 26 are schematic diagrams of application examples of the display system of FIG. 22.

Referring to FIG. 23, the display system 1000 of FIG. 22 may be applied to a smart watch 2000 including a display 2100 and a strap 2200.

The smart watch 2000 may be a wearable electronic device. For example, the smart watch 2000 may have a structure in which the strap 2200 is mounted on a user's wrist. Herein, the display system 1000 and/or the display device 1200 may be applied to the display 2100, to provide image data including time information to the user.

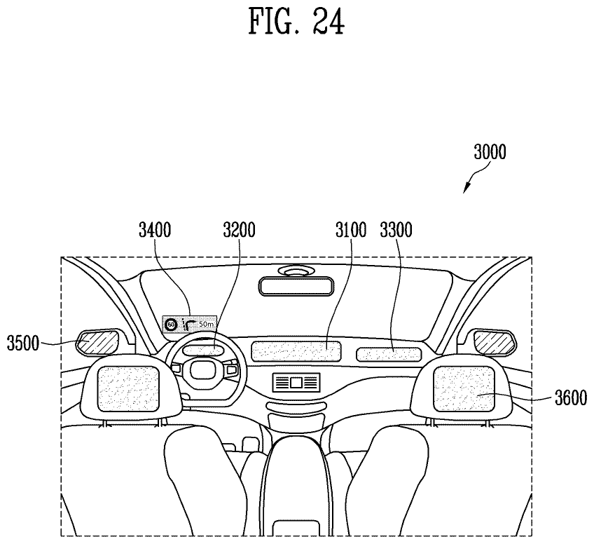

Referring to FIG. 24, the display system 1000 of FIG. 22 may be applied to an automotive display system 3000. Herein, the automotive display system 3000 may include a computing system equipped inside and/or outside a vehicle to provide image data.

For example, the display system 1000 and/or the display 1200 may be applied to at least one of an infotainment panel 3100, a cluster 3200, a co-driver display 3300, a head-up display 3400, a side mirror display 3500, and a rear seat display 3600 provided in the vehicle.

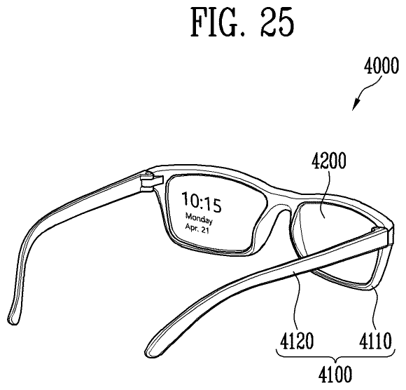

Referring to FIG. 25, the display system 1000 of FIG. 22 may be applied to smart glasses 4000. The smart glasses 4000 may be a wearable electronic device worn on a user's head. For example, the smart glasses 4000 may be a wearable device for augmented reality.

The smart glasses 4000 may include a frame 4100 and a lens 4200. The frame 4100 may include a housing 4110 for supporting the lens 4200 and a leg 4120 for the user's wearing. The leg 4120 may be connected to the housing 4110 using a hinge, to be folded or unfolded with respect to the housing 4110.

The frame 4100 may include a battery, a touchpad, a microphone, a camera, and the like. The frame 4100 may include a projector for outputting light, a processor for controlling an optical signal, and on the like.

The lens 4200 may include an optical member for transmitting light or reflecting light. For example, the lens 4200 may include glass, a transparent synthetic resin, and the like.

For user's eyes to perceive visual information, the lens 4200 may reflect an image by an optical signal emitted from the projector of the frame 4100 to the back of the lens 4200 (e.g., a surface facing the user's eyes). For example, the user may recognize the visual information such as time and date displayed on the lens 4200. The projector and/or the lens 4200 may be a sort of the display device. The display device 1200 may be applied to the projector and/or the lens 4200.

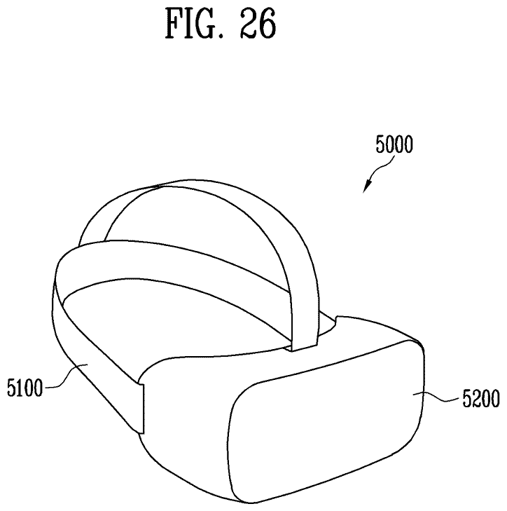

Referring to FIG. 26, the display system 1000 of FIG. 22 may be applied to a head-mounted display device 5000.

The head mounted display device 5000 may be a wearable electronic device worn on the user's head. For example, the head mounted display device 5000 may be a wearable device for virtual reality or mixed reality.

The head mounted display device 5000 may include a head mounting band 5100 and a display device receiving case 5200. The head mounting band 5100 may be connected to the display device receiving case 5200. The head mounting band 5100 may include a horizontal band and/or a vertical band for fixing the head mounted display device 5000 to the user's head. The horizontal band may be configured to surround a side part of the user's head, and the vertical band may be configured to surround an upper part of the user's head. However, embodiments are not limited thereto. For example, the head mounting band 5100 may be implemented in the form of a frame, a helmet, and on the like.

The display device receiving case 5200 may accommodate the display system 1000 and/or the display device 1200.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a cathode extending in a first direction;
an anode spaced apart from the cathode by a first gap in a second direction intersecting the first direction; and
a light-emitting element electrically connected to the cathode and the anode,
wherein a second gap in the second direction between the cathode and the anode facing each other is greater than the first gap.

2. The display device of claim 1, wherein the second gap changes along the first direction.

3. The display device of claim 2, wherein the second gap increases along the first direction.

4. The display device of claim 3, wherein
an edge of the anode facing the cathode is diagonal, and
an edge of the cathode facing the anode is straight.

5. The display device of claim 3, wherein
an edge of the anode facing the cathode is a curved shape, and
an edge of the cathode facing the anode is straight.

6. The display device of claim 5, wherein the curved shape is convex upward.

7. The display device of claim 5, wherein the curved shape is concave downward.

8. The display device of claim 2, wherein the second gap decreases along the first direction.

9. The display device of claim 8, wherein
an edge of the cathode facing the anode is diagonal, and
an edge of the anode facing the cathode is straight.

10. The display device of claim 1, wherein the second gap is constant along the first direction.

11. The display device of claim 10, wherein an edge of the anode facing the cathode and an edge of the cathode facing the anode each is diagonal.

12. The display device of claim 2, wherein the second gap increases and decreases along the first direction.

13. The display device of claim 12, wherein
an edge of the anode facing the cathode is V-shaped, and
an edge of the cathode facing the anode is straight.

14. The display device of claim 12, wherein
an edge of the cathode facing the anode is an inverted V shape, and
an edge of the anode facing the cathode is straight.

15. The display device of claim 12, wherein
an edge of the anode facing the cathode is V-shaped, and
an edge of the cathode facing the anode is an inverted V shape.

16. The display device of claim 2, wherein the second gap repeatedly increases and decreases along the first direction.

17. The display device of claim 16, wherein
an edge of the anode facing the cathode is saw-toothed, and
an edge of the cathode facing the anode is straight.

18. The display device of claim 16, wherein
an edge of the cathode facing the anode is saw-toothed, and
an edge of the anode facing the cathode is straight.

19. The display device of claim 16, wherein an edge of the anode facing the cathode and an edge of the cathode facing the anode each is saw-toothed.

20. An electronic device comprising:
a display device including a display element layer disposed on a substrate,
wherein the display element layer comprises:
a cathode extending in a first direction;
an anode spaced apart from the cathode by a first gap in a second direction intersecting the first direction; and
a light-emitting element electrically connected to the cathode and the anode, and
a second gap in the second direction between the cathode and the anode facing each other is greater than the first gap,
wherein the electronic device is at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.
